(19) United States
(12) Patent Application Publication
(10) Pub. No.: US 2015/0287958 A1
(43) Pub. Date: Oct. 8, 2015

(54) ORGANIC ELECTRO-LUMINESCENT DISPLAY DEVICE

(71) Applicant: Japan Display Inc., Tokyo (JP)

(72) Inventors: Yuya TANAKA, Tokyo (JP); Toshihiro Sato, Tokyo (JP)

(21) Appl. No.: 14/679,331

(22) Filed: Apr. 6, 2015

(30) Foreign Application Priority Data
Apr. 7, 2014 (JP) 2014-078983

(51) Int. Cl. H01L 51/52; H01L 51/50; H01L 27/32

(52) U.S. Cl. CPC H01L 51/5278; H01L 27/326; H01L 51/5092; H01L 51/5072; H01L 51/5056; H01L 51/5088; H01L 51/504; H01L 27/3209; H01L 51/0071

(57) ABSTRACT

An organic electro-luminescent display device is characterized in being provided with a substrate which is formed from an insulation material, a plurality of pixels which are arranged in a matrix shape in a display region of the substrate, and an organic layer which is formed spanning an adjacent pixel out of the plurality of pixels and includes a luminous layer, where the organic layer includes an anisotropic layer with greater electrical conductivity in a perpendicular direction with respect to the substrate than the electrical conductivity in a direction along the substrate.

### CROSS-REFERENCE TO RELATED APPLICATION

The present application claims priority from Japanese application JP2014-078983 filed on Apr. 7, 2014, the content of which is hereby incorporated by reference into this application.

### BACKGROUND OF THE INVENTION

1. Field of the Invention

The present invention relates to an organic electro-luminescent display device.

2. Description of the Related Art

In recent years, an image display device (referred to below as an “organic electro-luminescent display device”) has been practically applied which uses a self-luminous element referred to as an organic light emitting diode (OLED). Since the organic electro-luminescent display device uses a self-luminous element, compared with liquid crystal display apparatuses in the related art, not only are visibility and response speed superior, but it is also possible to further reduce the thickness since an auxiliary illumination device such as a back light is not necessary.

Pixels of the organic electro-luminescent display device contain organic light-emitting diodes, and the organic light-emitting diodes have a configuration where positive electrodes and negative electrodes interpose an organic layer which includes a luminous layer. Here, there are cases where the organic layer is formed spanning a plurality of the pixels of the organic electro-luminescent display device. In that case, adjacent pixels are divided into banks by being formed with an insulation material, and each pixel selectively emits light by each pixel being formed with at least one of a positive electrode or a negative electrode.

JP 2005-267990 A describes an organic light-emitting element which has a single-color light-emitting unit and a multi-color light-emitting unit which are interposed by an upper electrode and a lower electrode, and a charge-generating layer which is interposed by a plurality of light-emitting units, where the light-emission efficiency of the single-color light-emitting unit is equal to or less than the light-emission efficiency of the multi-color light-emitting unit.

In addition, JP 2009-520241 A describes an OLED display which is provided with color pixels of four colors, and is provided with driving means which adjusts the luminance of the pixels of each color to set the sum of the peak luminance of pixels determined to be in the color region so as to be smaller than the display peak luminance.

### SUMMARY OF THE INVENTION

In the case where the organic layer is formed spanning a plurality of pixels, when current flows to the organic light-emitting diode in order to cause a certain pixel to emit light, there are cases where the current flows out to adjacent pixels along the organic layer causing unintentional light emission to the adjacent pixels.

Therefore, an advantage of some aspects of the invention is to provide an organic electro-luminescent display device which suppresses unintentional light emission to pixels even in a case where the organic layer is formed spanning a plurality of pixels.

An organic electro-luminescent display device of the invention is characterized in being provided with a substrate which is formed from an insulation material, a plurality of pixels which are arranged in a matrix shape in a display region of the substrate, and an organic layer which is formed spanning an adjacent pixel out of the plurality of pixels and includes a luminous layer, where the organic layer includes an anisotropic layer with greater electrical conductivity in a perpendicular direction with respect to the substrate than the electrical conductivity in a direction along the substrate.

In addition, in the organic electro-luminescent display device of the invention, the anisotropic layer may be one or a plurality of layers which are included in the organic layer out of an electron injection layer, an electron transfer layer, a hole transfer layer, and a hole injection layer.

In addition, in the organic electro-luminescent display device of the invention, the anisotropic layer may be a p-type organic semiconductor layer, and may be one or a plurality of layers out of the hole transfer layer and the hole injection layer.

In addition, in the organic electro-luminescent display device of the invention, the anisotropic layer may be an n-type organic semiconductor layer, or may be one or a plurality of layers out of the electron injection layer and the electron transfer layer.

In addition, in the organic electro-luminescent display device of the invention, the organic layer includes a plurality of luminous layers and a charge-generating layer, and the plurality of luminous layers are arranged so as to interpose the charge-generating layer, and the anisotropic layer may be one or a plurality of layers out of the layers which are included in the organic layer.

In addition, in the organic electro-luminescent display device of the invention, the charge-generating layer is formed by layering a p-type organic semiconductor layer and an n-type organic semiconductor layer, and the anisotropic layer may be at least one of the p-type organic semiconductor layer and the n-type organic semiconductor layer.

In addition, in the organic electro-luminescent display device of the invention, the anisotropic layer may include at least one of bis-(1,2,5-thiadiazole)-p-quinone bis(1,3-dithiol), a perylene tetracarboxylic diimide compound, perylene-3,4,9,10-tetracarboxylic dianhydride, and hexaazatrinaphthylene.

### BRIEF DESCRIPTION OF THE DRAWINGS

FIG. 1 is a perspective diagram of an organic electro-luminescent display device according to a first embodiment of the invention.

FIG. 2 is a wiring diagram of an organic electro-luminescent panel according to the first embodiment of the invention.

FIG. 3 is a circuit diagram of the organic electro-luminescent panel according to the first embodiment of the invention.

FIG. 4 is a cross sectional diagram of a pixel portion of the organic electro-luminescent panel according to the first embodiment of the invention.

FIG. 5 is an enlarged view of an organic layer in the first embodiment of the invention.

FIG. 6 is a cross sectional diagram of a pixel portion of an organic electro-luminescent panel according to a second embodiment of the invention.

FIG. 7 is an enlarged view of an organic layer in the second embodiment of the invention.

FIG. 8 is an enlarged view of a charge-generating layer in the second embodiment of the invention.

### DETAILED DESCRIPTION OF THE INVENTION

Each embodiment of the invention will be described below with reference to the drawings. Here, the disclosure is merely an example, and naturally any embodiment which can be easily conceived of by a person skilled in the art by appropriately modifying maintaining the gist of the invention is included within the scope of the invention. In addition, in order to make the explanation clearer, there are cases where width, thickness, form, or the like of the drawings is represented schematically compared to the actual aspect, but is merely an example and does not limit the interpretation of the invention. In addition, in the specification and each of the drawings, the same reference numerals are given for the same components as prior described in relation to the previously mentioned drawings, and detailed description is omitted as appropriate.

### First Embodiment

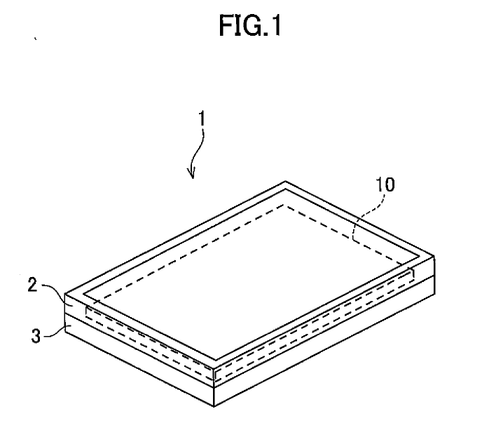

FIG. 1 is a perspective diagram illustrating an organic electro-luminescent display device 1 according to a first embodiment of the invention. The organic electro-luminescent display device 1 is configured from an upper frame 2, a lower frame 3, and an organic electro-luminescent panel 10 which is fixed so as to be interposed by the upper frame 2 and the lower frame 3. Here, according to necessity, the organic electro-luminescent display device may be configured by a single organic electro-luminescent panel without the upper frame 2 and the lower frame 3.

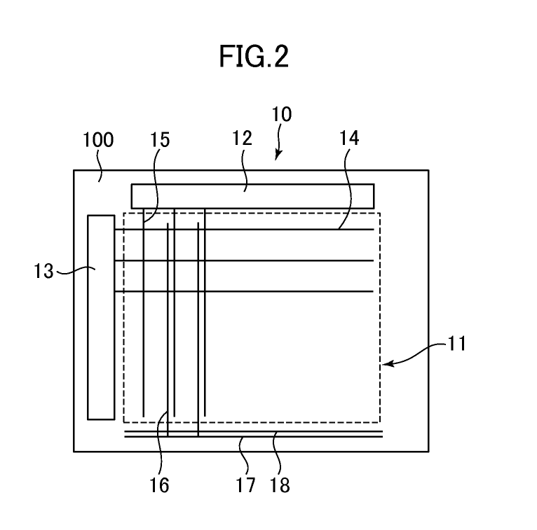

FIG. 2 is a wiring diagram of the organic electro-luminescent panel 10 according to the first embodiment of the invention. The organic electro-luminescent panel 10 controls each of the pixels in a display region 11 on a substrate 100 which is formed from an insulation material such as glass using a data driving circuit 12 and a scanning driving circuit 13, and displays an image. Here, the data driving circuit 12 is an integrated circuit (IC) which generates and transmits a data signal which is sent to each pixel, and the scanning driving circuit 13 is an IC which generates and transmits a gate signal to a thin film transistor (TFT) which is provided on the pixel. Here, in FIG. 2 the data driving circuit 12 and the scanning driving circuit 13 are described as being formed in two locations, but may be built-in to one IC, and may be formed using a circuit which is directly wired onto the substrate.

A scanning line 14 which conveys a signal from the scanning driving circuit 13 is connected to a gate electrode of a switch transistor 30 as shown in the following drawing. In addition, a data line 15 which conveys a signal from the data driving circuit 12 is connected to a source or a drain electrode of the switch transistor 30. In a potential wiring 16, a potential for emitting light to an organic light-emitting diode 60 is imparted and a source or a drain electrode of a driver transistor 20 is connected. A first potential supply wiring 17 and a second potential supply wiring 18 are connected to a potential supply source and are connected to the potential wiring 16 via a transistor.

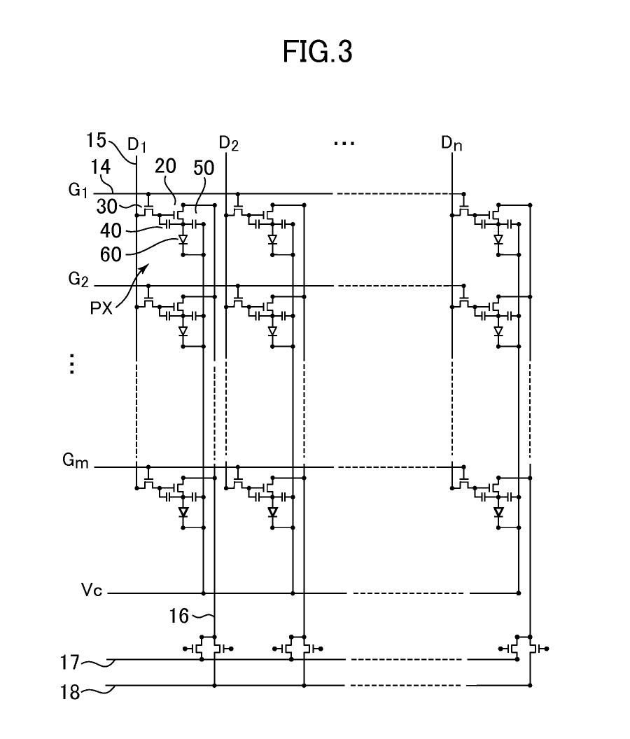

FIG. 3 is a circuit diagram of the organic electro-luminescent panel 10 according to the first embodiment of the invention. In the display region 11 of the organic electro-luminescent panel 10, n data lines 15 are formed from D1 to Dn and m scanning lines 14 are formed from G1 to Gm. A plurality of pixels PX are arranged in a matrix shape in the extension direction of the scanning lines 14 and the extension direction of the data lines 15. For example, the pixel PX is formed in a portion which is enclosed by G1, G2, D1, and D2.

The first scanning line G1 is connected to a gate electrode of the switch transistor 30, and when a signal from the scanning driving circuit 13 is applied, the switch transistor 30 is switched to the on state. Therefore, when a signal from the data driving circuit 12 is applied to the first data line D1, charge is accumulated in a storage capacitor 40, a voltage is applied to the gate electrode of the driver transistor 20, and the driver transistor 20 is switched to the on state. Here, even if the switch transistor 30 is in the off state, the driver transistor 20 is in the on state for a certain period due to the charge which accumulates in the storage capacitor 40. A positive electrode of the organic light-emitting diode 60 is connected to the potential wiring 16 through a source or drain of the driver transistor 20, and since a negative electrode of the organic light-emitting diode 60 is fixed at a reference potential Vc, current flows to the organic light-emitting diode 60 according to the gate voltage of the driver transistor 20, and the organic light-emitting diode 60 emits light. In addition, an additional capacitor 50 is formed between the positive electrode and the negative electrode of the organic light-emitting diode 60. The additional capacitor 50 exhibits an effect where voltage which is written to the storage capacitor 40 is stable and contributes to the stable operation of the organic light-emitting diode 60.

Here, the wiring diagram of FIG. 2 and the circuit diagram of FIG. 3 are examples, and other wiring and circuit configurations may be adopted.

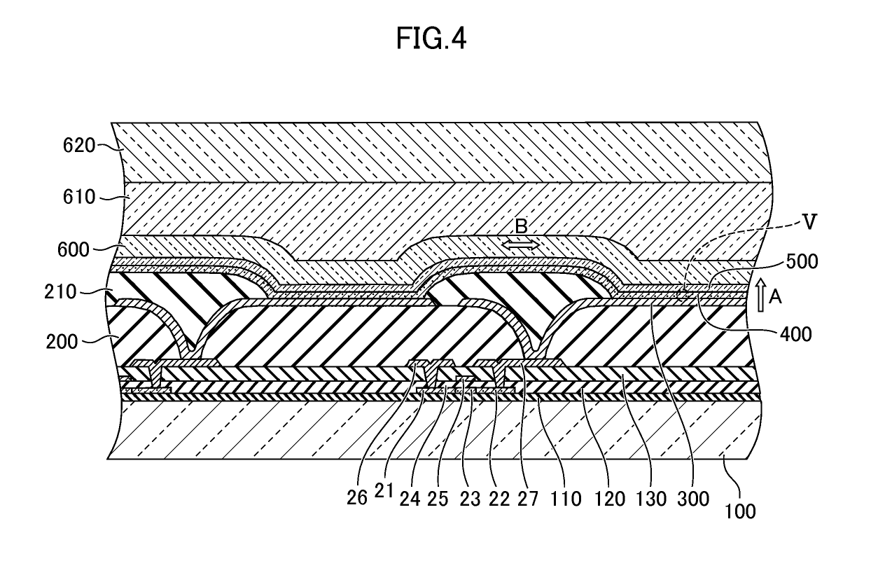

FIG. 4 is a cross sectional diagram of a pixel portion of the organic electro-luminescent panel 10 according to the first embodiment of the invention. FIG. 4 shows a connection state of the driver transistor 20 and the organic light-emitting diode 60 in two adjacent pixels. A panel substrate 100 made from glass or the like is arranged on the lowermost layer, on top of that a first base film 110 made from SiNx or the like is formed, and on top of that a second base film 120 made from SiOx or the like is formed. On top of the second base film 120 a drain electrode layer 21, a source electrode layer 22, and a channel layer 23 of the driver transistor 20 are formed. Then, after a gate insulation film 24 is formed so as to cover the drain electrode layer 21, the source electrode layer 22, the channel layer 23, and the second base film 120, a gate electrode layer 25 is formed on top of the channel layer 23. Here, in the present embodiment, layers consisting of the drain electrode layer 21, the source electrode layer 22, and the channel layer 23 are formed with polycrystalline silicon. Here, the channel layer 23 may be formed with amorphous silicon or the like.

A first inter-layer insulation film 130 is layered so as to cover the gate electrode layer 25 and the gate insulation film 24, and through holes are formed which respectively reach the drain electrode layer 21 and the source electrode layer 22. A drain electrode 26 and a source electrode 27 are formed in the respective through holes, and a second inter-layer insulation film 200 is layered so as to cover the drain electrode 26, the source electrode 27, and the first inter-layer insulation film 130. In the second inter-layer insulation film 200, a through hole is formed which reaches the source electrode 27 of the driver transistor 20 which controls each of the pixels. After this, a lower electrode 300 is formed from a conductive material such as a metal material so as to cover the second inter-layer insulation film 200 where a through hole is provided and to be electrically connected to the source electrode 27 at the bottom of the through hole. The lower electrode 300 is formed in each of the pixels and the lower electrode 300 of the adjacent pixels is electrically insulated.

A pixel separation film 210 (bank) is formed using an insulation material on the lower electrode 300 and an organic layer 400 is formed on the pixel separation film 210 and the lower electrode 300. The organic layer 400 is formed spanning the adjacent pixels and includes at least a luminous layer. Here, a region where the lower electrode 300 and the organic layer 400 come into contact is a light-emitting region, and the pixel separation film 210 defines an outer edge of the light-emitting region. Here, the organic layer 400 may be formed on each different color pixel or formed spanning adjacent same color pixels. An upper electrode 500 is formed spanning adjacent pixels using a transparent electrode such as indium tin oxide (ITO), indium zinc oxide (IZO), and zinc oxide (ZnO) on the organic layer 400. The upper electrode 500 may be formed spanning all of the pixels PX which are arranged in a matrix shape.

According to necessity, a transparent sealing layer 600 is formed on the upper electrode 500. The sealing layer 600 is desirable in order to prevent infiltration of water and air into the organic layer 400, and is desirably formed from a material with high gas barrier characteristics. In detail, the sealing layer 600 may be formed using a dense inorganic material such as SiN, or a layered film of inorganic material and organic material. Furthermore, a transparent sealing member 620 is arranged with respect to visible light above the sealing layer 600, and closes and seals a frame portion of the organic electro-luminescent panel 10 using a sealing material. It is desirable for the sealing member 620 to also be a member with high gas barrier characteristics. In detail, it is possible to use a glass substrate or a plastic substrate where a process is executed for high gas barrier characteristics. A filler 610 made from a resin material or an inert gas such as nitrogen may seal a gap between the sealing member 620 and the sealing layer 600, and the filler 610 may be a transparent substance through which it is difficult to release water which leads to deterioration of the organic layer 400.

In the organic electro-luminescent display device 1 according to the present embodiment, a material where white light emission is obtained is adopted as the organic layer 400, sub-pixels of three source colors are realized by arranging color filters which correspond to the three source colors (red, green, and blue) on the sealing member 620, and full color display is performed. Here, the color filter may be provided in a region which superimposes the light-emitting region of the pixel, and a black matrix may be provided outside of that region. In addition, sub-pixels of white other than red, green, and blue may be provided.

As described above, in the organic electro-luminescent display device 1, the switch transistor 30 is switched on by a scanning signal and a data signal is sent, and pixels are caused to selectively emit light by switching the driver transistor 20 on. Here, for example, when the driver transistor 20 of the pixel on the right side in FIG. 4 is set to the on state, the lower electrode 300 on the right side is connected to the first potential supply wiring 17 and the second potential supply wiring 18, and a potential difference (a voltage) is generated between the lower electrode 300 and the upper electrode 500 which is maintained at the reference potential Vc. As a result, holes are injected from the side of the lower electrode 300 which is a positive electrode to the organic layer 400, and electrons are injected from the side of the upper electrode 500 which is a negative electrode to the organic layer 400. The electrons and holes which are injected reach the luminous layer of the respective organic layers 400, recombination of the electrons and holes occurs, and light with a predetermined wavelength is generated. The light which is generated in the luminous layer is released to the upper electrode 500 side, passes through the color filters, and then is visually recognized by a user.

Here, as shown in FIG. 4, in a case where the organic layer 400 spans adjacent pixels, there is a concern that not only does current flow in the direction perpendicular to the substrate 100 (the direction of the arrow A), but current also flows in the direction along the substrate 100 (the direction of the arrow B). When current flows in the direction B along the organic layer 400, current flows to the luminous layer of the adjacent pixels, and unintentional light emission to the adjacent pixels is caused. In the case of the above example, regardless of the lower electrode 300 at the right side in FIG. 4 being selected, there is a concern that light is emitted to the pixels at the left side along with the pixels at the right side.

In the present embodiment, out of the layers which are included in the organic layer 400, unintentional light emission to the adjacent pixels of all the layers or some of the layers is suppressed by forming an anisotropic layer which has anisotropy with electrical conductivity. The anisotropic layer is a layer with greater electrical conductivity in the A direction which is perpendicular with respect to the substrate 100 than the electrical conductivity in the B direction which is along the substrate 100. In other words, the anisotropic layer is a layer with greater electrical conductivity in the layering direction of the layer than the electrical conductivity in the extension direction of the layer.

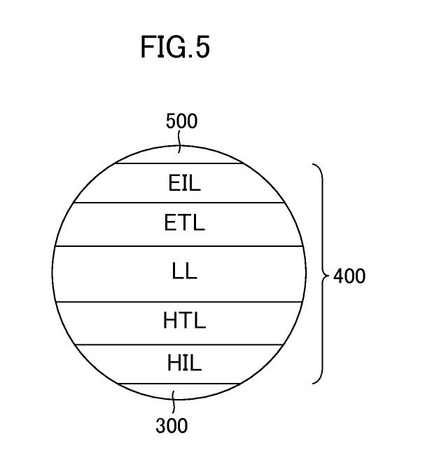

FIG. 5 is an enlarged view of the organic layer 400 in the first embodiment of the invention. FIG. 5 is an enlarged view of a portion of a circle V which is drawn with a dotted line in FIG. 4. The organic layer 400 has a structure where a hole injection layer (HIL), a hole transfer layer (HTL), a luminous layer (LL), an electron transfer layer (ETL), and an electron injection layer (EIL) are layered from the lower electrode 300 side in that order. Here, the hole injection layer (HIL) and the hole transfer layer (HTL) are formed with a p-type organic semiconductor, and the electron injection layer (EIL) and the electron transfer layer (ETL) are formed with an n-type organic semiconductor. The luminous layer (LL) is made up of a guest molecule which is a luminous molecule and a host molecule which holds the guest molecule. Here, the guest molecule is selected so as to obtain a desired luminous color. The host molecule may be formed with either the p-type organic semiconductor or the n-type organic semiconductor.

In the present embodiment, all of or some of the layers out of the hole injection layer (HIL), the hole transfer layer (HTL), the luminous layer (LL), the electron transfer layer (ETL), and the electron injection layer (EIL) may be anisotropic layers. For example, in a case where the electron injection layer (EIL) is an anisotropic layer, movement of the electrons which relates to the extension direction B of the electron injection layer (EIL) is suppressed more than movement of the electrons which relates to the layering direction A of the electron injection layer (EIL), electrons are suppressed from flowing out to adjacent pixels, and unintentional light emission is suppressed. Naturally, the layers which configure the organic layer 400 other than the electron injection layer (EIL) may be anisotropic layers. In addition, the effect where unintentional light emission of adjacent pixels is suppressed is exhibited best in a case where all of the layers which configure the organic layer 400 are anisotropic layers.

In a case where the hole injection layer (HIL) and the hole transfer layer (HTL) are anisotropic layers, it is preferable to use a p-type organic semiconductor layer which has anisotropy with electrical conductivity. Bis-(1,2,5-thiadiazole)-p-quinone bis(1,3-dithiol) (referred to below as BTQBT) is given as an example of the p-type organic semiconductor layer. In addition, either of a perylene tetracarboxylic diimide compound (referred to below as PTCDI) or hexaazatrinaphthylene (referred to below as HATNA) may be used. In a case where the hole injection layer (HIL) is an anisotropic layer, it is preferable to adopt a material with a value close to the work function of the lower electrode 300.

In a case where the electron transfer layer (ETL) and the electron injection layer (EIL) are anisotropic layers, it is preferable to use an n-type organic semiconductor which has anisotropy with electrical conductivity. In detail, it is preferable to use perylene-3,4,9,10-tetracarboxylic dianhydride (referred to below as PTCDA), or PTCDI. In addition, HATNA may be used.

In a case where the luminous layer (LL) is an anisotropic layer, it is possible to use any one of BTQBT, PTCDI, HATNA, and PTCDA as the host molecule.

There are cases where the material which forms the anisotropic layer has a planar portion with respect to the molecule structure. In that case, anisotropy with electrical conductivity is realized by aligning the planar portion parallel to the substrate 100. That is, due to n electrons being distributed in a direction which is orthogonal to the planar portion of the molecule structure, the direction perpendicular to the substrate 100 has relatively high electrical conductivity where n orbital overlap is high and the direction along the substrate 100 has relatively low electrical conductivity where n orbital overlap is low.

Here, it is possible to use a material which has anisotropy with electrical conductivity other than the examples above as the material which forms the anisotropic layer.

### Second Embodiment

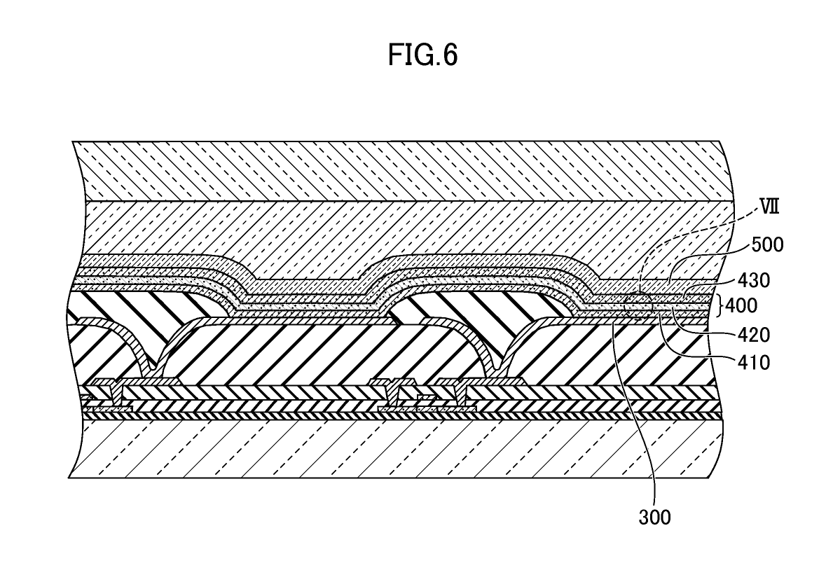

FIG. 6 is a cross sectional diagram of the pixel portion of the organic electro-luminescent panel 10 according to the second embodiment of the invention. The organic electro-luminescent panel 10 according to the second embodiment is different compared to the organic electro-luminescent panel 10 according to the first embodiment in the configuration of the organic layer 400, and is the same in the other configuration. The organic layer 400 in the second embodiment of the invention has a configuration where a first organic layer 410, a charge-generating layer 420, and a second organic layer 430 are layered. The organic light-emitting diode 60 according to the present embodiment is a so-called tandem-type organic light-emitting diode 60, the first organic layer 410 and the second organic layer 430 each include a luminous layer, and the charge-generating layer 420 is arranged so as to be interposed by two luminous layers. Here, the two luminous layers may have luminous colors which are each different.

In the present embodiment, unintentional light emission to adjacent pixels is suppressed by a layer which includes any one of the first organic layer 410, the charge-generating layer 420, and the second organic layer 430 forming the anisotropic layer which has anisotropy with electrical conductivity. The anisotropic layer is preferably formed with the aforementioned materials, and is a layer with greater electrical conductivity in the direction which is perpendicular with respect to the substrate 100 than the electrical conductivity in the direction which is along the substrate 100.

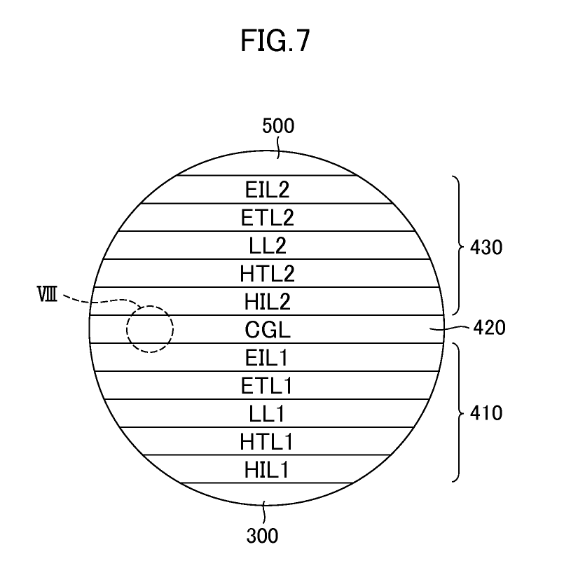

FIG. 7 is an enlarged view of the organic layer 400 in the second embodiment of the invention. FIG. 7 is an enlarged view of a portion of a circle VII which is drawn with a dotted line in FIG. 6. The organic layer 400 in the present embodiment is formed where a first hole injection layer (HIL1), a first hole transfer layer (HTL1), a first luminous layer (LL1), a first electron transfer layer (ETL1), and a first electron injection layer (EIL1), a charge-generating layer (CGL), a second hole injection layer (HIL2), a second hole transfer layer (HTL2), a second luminous layer (LL2), a second electron transfer layer (ETL2), and a second electron injection layer (EIL2) are layered from the lower electrode 300 side in that order. Here, all or some out of these layers may be anisotropic layers.

For example, it is possible to efficiently suppress a carrier along the charge-generating layer (CGL) from flowing out to adjacent pixels by the charge-generating layer (CGL) being an anisotropic layer in a case where electrical conductivity is high compared to another layer which configures the organic layer 400, and unintentional light emission to adjacent pixels is suppressed. Naturally, unintentional light emission to adjacent pixels is further suppressed by other layers being anisotropic layers while the charge-generating layer (CGL) is an anisotropic layer.

In detail, in a case where any of the first hole injection layer (HIL1), the first hole transfer layer (HTL1), the second hole injection layer (HIL2), and the second hole transfer layer (HTL2) is an anisotropic layer, it is preferable to use any one or a combination of BTQBT, PTCDI, and HATNA.

In addition, in a case where any of the first electron transfer layer (ETL1), the first electron injection layer (EIL1), the second electron transfer layer (ETL2), and the second electron injection layer (EIL2) is an anisotropic layer, it is preferable to use PTCDA.

In a case where either of the first luminous layer (LL1) and the second luminous layer (LL2) is an anisotropic layer, it is possible to use BTQBT, PTCDI, HATNA, and PTCDA as the host molecule.

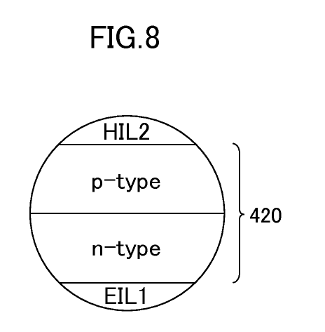

FIG. 8 is an enlarged view of the charge-generating layer 420 in the second embodiment of the invention. FIG. 8 is an enlarged view of a portion of a circle VIII which is drawn with a dotted line in FIG. 7. The charge-generating layer 420 of the present embodiment is formed where an n-type organic semiconductor layer (n-type) and a p-type organic semiconductor layer (p-type) are layered from the first electron injection layer (EIL1) side in that order. Here, the n-type organic semiconductor layer (n-type) supplies electrons to the first electron injection layer (EIL1) and the p-type organic semiconductor layer (p-type) supplies holes to the second hole injection layer (HIL2).

In a case where the charge-generating layer 420 is an anisotropic layer, the anisotropic layer includes, for example, PTCDA, PTCDI, BTQBT, and HATNA. Particularly in a case where the n-type organic semiconductor layer (n-type) which configures the charge-generating layer 420 is an anisotropic layer, it is preferable, for example, to form the n-type organic semiconductor layer (n-type) using either of PTCDA or PTCDI.

In addition, in a case where the p-type organic semiconductor layer (p-type) which configures the charge-generating layer 420 is an anisotropic layer, it is preferable, for example, to form the p-type organic semiconductor layer (p-type) using BTQBT.

Both the n-type organic semiconductor layer (n-type) and the p-type organic semiconductor layer (p-type) which are included in the charge-generating layer 420 may be anisotropic layers, in that case it is possible to suppress both the electrons and holes from flowing out to the adjacent pixels, and it is possible to more reliably suppress unintentional light emission to the adjacent pixels.

In the present embodiment, a case of the tandem-type organic light-emitting diode 60 which has the first organic layer 410, the charge-generating layer 420, and the second organic layer 430 is indicated, but even in a case of the tandem-type organic light-emitting diode 60 which has three or more organic layers and two or more charge-generating layers, it is possible to suppress unintentional light emission to the adjacent pixels by applying the invention. In that case, it is possible to efficiently suppress the carrier from flowing out to adjacent pixels by a plurality of the charge-generating layers where comparative electrical conductivity is high being anisotropic layers.

The entirety of the organic electro-luminescent display device which is obtained by a person skilled in the art executing appropriate design changes based on the organic electro-luminescent display device 1 described above as the embodiment of the invention is limited to being included in the gist of the invention, and belongs in the scope of the invention.

In the category of the concept of the invention, a person skilled in the art could conceive of each type of modification example and correction example, and it is understood that these modification examples and correction examples belong to the scope of the invention. For example, with respect to each of the embodiments described above, a person skilled in the art could add, remove, or perform design changes to configuration elements, add or omit processes, or perform modifications of conditions limited to providing the gist of the invention and included in the scope of the invention.

In addition, the invention in the present embodiment is obvious from the description in the other actions and effects which are produced by the aspects described above or it is understood that a person skilled in the art could appropriately conceive of actions and effects naturally produced by the invention.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic electro-luminescent display device comprising:
a substrate which is formed from an insulation material;
a plurality of pixels which are arranged in a matrix shape in a display region of the substrate; and
an organic layer which is formed spanning an adjacent pixel out of the plurality of pixels and includes a luminous layer,
wherein the organic layer includes an anisotropic layer with greater electrical conductivity in a perpendicular direction with respect to the substrate than the electrical conductivity in a direction along the substrate.

2. The organic electro-luminescent display device according to claim 1,
wherein the anisotropic layer is one or a plurality of layers which are included in the organic layer out of an electron injection layer, an electron transfer layer, a hole transfer layer, and a hole injection layer.

3. The organic electro-luminescent display device according to claim 2,
wherein the anisotropic layer is a p-type organic semiconductor layer, and is one or a plurality of layers out of the hole transfer layer and the hole injection layer.

4. The organic electro-luminescent display device according to claim 2,
wherein the anisotropic layer is an n-type organic semiconductor layer, and is one or a plurality of layers out of the electron injection layer and the electron transfer layer.

5. The organic electro-luminescent display device according to claim 1,
wherein the organic layer includes a plurality of luminous layers and a charge-generating layer, and the plurality of luminous layers are arranged so as to interpose the charge-generating layer, and the anisotropic layer is one or a plurality of layers out of the layers which are included in the organic layer.

6. The organic electro-luminescent display device according to claim 5,
wherein the charge-generating layer is formed by layering a p-type organic semiconductor layer and an n-type organic semiconductor layer, and the anisotropic layer is at least one of the p-type organic semiconductor layer and the n-type organic semiconductor layer.

7. The organic electro-luminescent display device according claim 1,
wherein the anisotropic layer includes at least one of bis-(1,2,5-thiadiazole)-p-quinone bis(1,3-dithiol), a perylene tetracarboxylic diimide compound, perylene-3,4,9,10-tetracarboxylic dianhydride, and hexaazatrinaphthylene.
